(19) United States
(12) Patent Application Publication
(10) Pub. No.: US 2004/0017118 A1
(43) Pub. Date: Jan. 29, 2004

(54) System and method for estimating electric motor operating parameters

(76) Inventor: Yehia El-Ibiary, Simpsonville, SC (US)

Correspondence Address: Alexander M. Gerasimow, Allen-Bradley Company, LLC, 1201 South Second Street, Milwaukee, WI, 53204-2496, US

(21) Appl. No.: 10/201,007

(22) Filed: Jul. 23, 2002

(51) Int. Cl. G01R 15/00; G06F 19/00

(52) U.S. Cl. 310/68 B; 702/127; 702/57; 73/862.08

(57) ABSTRACT

A technique for establishing a value of a rotor parameter indirectly is provided. The rotor parameter may be electrical resistance of the rotor, rotor temperature, rotor current, rotor torque, etc. The technique may comprise obtaining other motor data and data obtained during operation of the motor directly and then using an algorithm to establish an estimated value of the rotor parameter. A system for establishing an estimated value of a rotor parameter also is provided. In addition, an electric motor having a system that is operable to establish an estimated value of a rotor parameter is provided.

### BACKGROUND OF THE INVENTION

The present invention relates generally to the field of electric motors. More particularly, the invention relates to a novel technique for estimating certain unknown operating parameters of an induction motor based on known motor data and known motor operating parameters.

A wide variety of electric motors are available and are currently in use throughout a range of industrial applications. In general, such motors include a stator provided in a motor housing, and a rotor surrounded at least partially by the stator and supported for rotation within the housing. The stator and rotor may be mechanically and electrically configured in various manners, depending upon the application, the power available to drive the motor, and so forth. In general, however, electric power is applied to the stator and the rotor is thereby driven in rotation to produce rotary motion and transmit mechanical power via an output shaft which may be coupled to a driven load.

Many motor operating parameters may be measured easily without interfering with the normal operation of the motor. However, other motor parameters may not be measured without interfering with the normal operation of the motor or may be difficult or expensive to acquire. For example, it may be desirable to maintain the temperature of the rotor below a specific temperature when the motor is located within an explosive environment. However, in induction motors it is extremely difficult to measure the rotor temperature. Non-contact temperature probes can be very expensive and occupy a large space within the motor. Similarly, the typical measurement of the torque of the motor requires the motor to be disconnected from its load, interfering significantly with the operation of the motor and any operation associated with the motor.

A need exists for a system for providing certain electric motor operating information such as rotor temperature and torque, that is less expensive than conventional methods and which does not interfere with the operation of the electric motor.

### SUMMARY OF THE INVENTION

According to one aspect of the present invention, a technique is provided for establishing an estimated value of a variable motor parameter based on motor electrical input data, known rotor and stator electrical characteristics data, and rotor speed data. The technique may be used by a processing module within an instrumentation device that may be added to an electric motor or supplied as part of the electric motor. The instrumentation device or motor also may have a visual display to provide a visual indication of the estimated value of the variable motor parameter or a control module to enable a user to communicate with and control the processor. A communication module may also be included to enable data to be provided to the processing module.

According to another aspect of the present invention, a technique is provided for establishing an estimated value of the electrical resistance of the rotor of an electric motor based on the speed of the rotor. The technique may be used by a processing module within an instrumentation device that may be added to an electric motor or supplied as part of the electric motor. The electrical resistance of the rotor may then be used to establish other motor parameters, such as the electrical current flowing in the rotor, the rotor temperature, the rotor torque, and the efficiency of the motor.

### BRIEF DESCRIPTION OF THE DRAWINGS

The foregoing and other advantages and features of the invention will become apparent upon reading the following detailed description and upon reference to the drawings in which:

FIG. 1 is a cut-away view of an induction motor, in accordance with an exemplary embodiment of the present technique;

FIG. 2 is an equivalent electrical circuit for the induction motor of FIG. 1;

FIG. 3 is a system for estimating various motor parameters during operation of the motor, in accordance with an exemplary embodiment of the present technique; and

FIG. 4 is a block diagram of a process for estimating various motor parameters during operation of the motor, using the system of FIG. 3, in accordance with an exemplary embodiment of the present technique.

### DETAILED DESCRIPTION OF SPECIFIC EMBODIMENTS

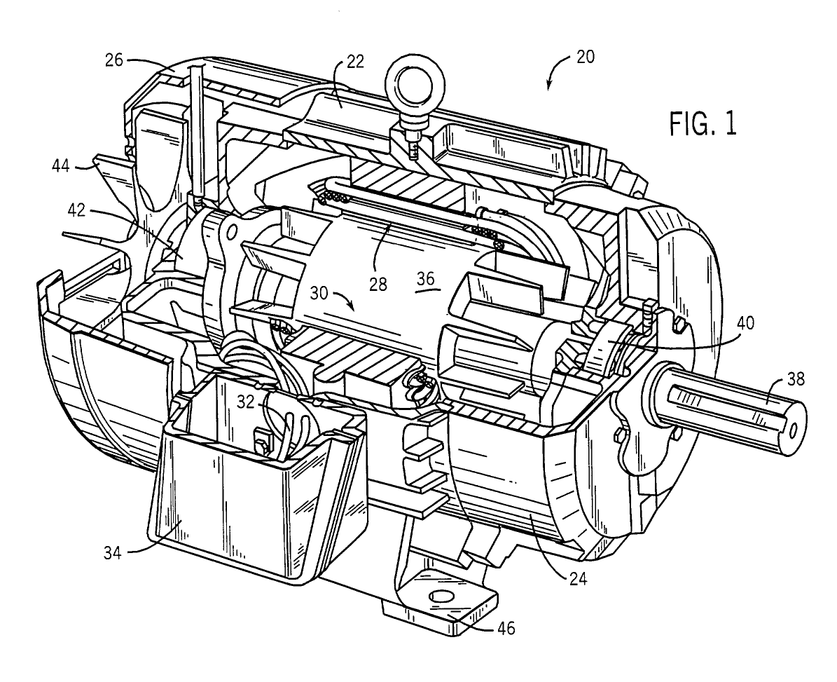

Turning now to the drawings, and referring first to FIG. 1, an electric motor is shown and designated generally by the reference numeral 20. In the embodiment illustrated in FIG. 1, motor 20 is an induction motor housed in a conventional NEMA enclosure. Accordingly, motor 20 includes a frame 22 open at front and rear ends and capped by a front end cap 24 and a rear end cap 26. The frame 22, front end cap 24, and rear end cap 26 form a protective shell, or housing, for a stator assembly 28 and a rotor assembly 30. Stator windings are electrically interconnected to form groups, and the groups are, in turn, interconnected. The windings are further coupled to terminal leads 32. The terminal leads 32 are used to electrically connect the stator windings to an external power cable (not shown) coupled to a source of electrical power. Energizing the stator windings produces a magnetic field that induces rotation of the rotor assembly 30. The electrical connection between the terminal leads and the power cable is housed within a conduit box 34.

In the embodiment illustrated, rotor assembly 30 comprises a cast rotor 36 supported on a rotary shaft 38. As will be appreciated by those skilled in the art, shaft 38 is configured for coupling to a driven machine element (not shown), for transmitting torque to the machine element. Rotor 36 and shaft 38 are supported for rotation within frame 22 by a front bearing set 40 and a rear bearing set 42 carried by front end cap 24 and rear end cap 26, respectively. In the illustrated embodiment of electric motor 20, a cooling fan 44 is supported for rotation on shaft 38 to promote convective heat transfer through the frame 22. The frame 22 generally includes features permitting it to be mounted in a desired application, such as integral mounting feet 46. As will be appreciated by those skilled in the art, however, a wide variety of rotor configurations may be envisaged in motors that may employ the techniques outlined herein, including wound rotors of the type shown, and so forth. Similarly, the present technique may be applied to a variety of motor types having different frame designs, mounting and cooling styles, and so forth.

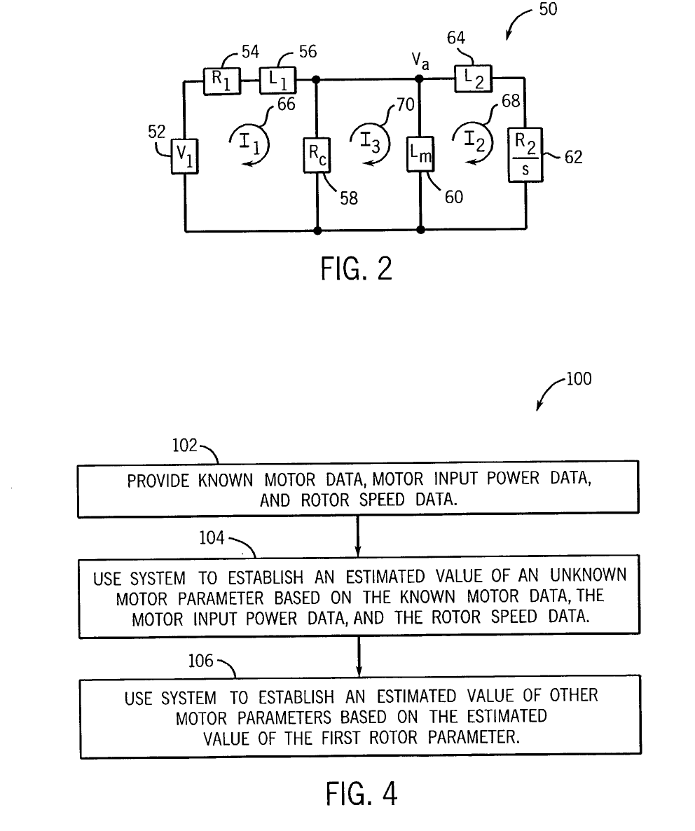

Referring generally to FIG. 2, a single-phase equivalent circuit for steady state operation of the induction motor of FIG. 1 is shown and designated generally by the reference numeral 50. The induction motor is powered by an AC power source, designated by reference numeral 52, having a voltage amplitude V₁, and a frequency ω. The stator of the motor has an electrical resistance R₁, as represented by reference numeral 54, and a leakage inductance L₁, as represented by reference numeral 56. The motor also has core loss resistance R_{c} due to core losses in the stator and rotor, designated by referenced numeral 58. The motor also has a magnetizing inductance Lₘ, designated by reference numeral 60. The rotor also has an electrical resistance R₂, designated by reference numeral 62. As illustrated, the rotor resistance R₂ is modified by dividing the rotor resistance R₂ by the slips of the motor. Finally, the rotor also has a leakage inductance L₂, as represented by reference numeral 64. Electric current flows through the stator to produce the magnetic field. The electric current I₁ through the stator is represented by arrow 66. In addition, the magnetic field induces an electric current I₂ in the rotor, as represented by arrow 68. Finally, electric current flowing through the core loss resistance R_{c} and the magnetizing inductance Lₘ is represented by arrow 70.

In a typical AC circuit, voltage and current vary over time. The inductors within the motor oppose the change in current and alternately store energy in a magnetic field when the current is increasing, and convert the magnetic field to current when the current is decreasing. The power that is alternately stored and released by the inductors in the circuit is known as the “reactive power.” In addition, the resistors of the circuit dissipate power as heat and the load utilizes part of the input power, this power is called the “real power.” The product of the total voltage and the total current in the circuit is known as the “apparent power.” The ratio between the real power and the apparent power of a load in an AC circuit is called the power factor of the load. In an inductive circuit, such as an induction motor, the voltage leads the current by an angle, known as the phase angle φ. The cosine of the phase angle is the power factor.

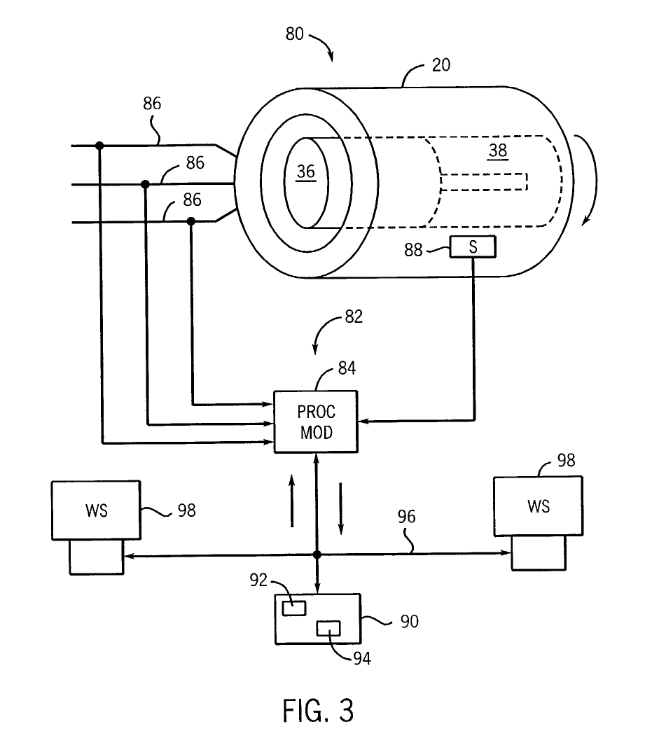

Referring generally to FIG. 3, a system for providing estimated values of various motor operating parameters is shown and designated generally by reference numeral 80. In the illustrated embodiment, the motor 20 is a three-phase induction motor. The system 80 comprises an electronics module 82 that is electrically coupleable to the motor 20. The electronics module 82 utilizes data to establish values of various unknown motor operating parameters. The electronics module 82 may be provided as part of a motor or in kit form as a component to add to an existing installed motor. In the illustrated embodiment, the electronics module 82 has a processor module 84. Preferably, the processor module 84 utilizes a processor (not shown) and operates in accordance with programming instructions to produce estimates of various motor parameters. The processor module 84 may have analog-to-digital converters for converting analog motor data into digital data. In this embodiment, the processor module 84 is electrically coupled to each phase 86 of the input power to the motor 20 to enable the module to receive input voltage and current data. The input voltage data may be the line-to-line voltage or the phase voltage. The average phase voltage for a star connection may be established by averaging the three line-to-line voltages and dividing by the \sqrt{3}. The average line current is the phase current. Input power data also may be obtained directly or calculated from the stator voltage and current data. The power factor of the input power may also be obtained. A speed sensor 88 also is electrically coupled to the processor module 84. The slip s may be determined from the rotor speed. The speed sensor 88 may be integral with the motor or a separate device coupled to the processor module 84. The speed sensor 88 may measure the speed of the rotor 36 directly or the speed of the shaft 38 coupled to the rotor 36. The electronics module 82 also receives the values of known motor parameters, such as stator leakage inductance L₁.

In the illustrated embodiment, the processor module 84 outputs the estimated parameters, e.g. torque, rotor temperature, rotor resistance R₂, and rotor leakage inductance, to a control module or panel 90. Preferably, the control module 90 has a visual display 92 to provide visual indications of the estimated parameters. In addition, it is preferred that the control module 90 have a keypad or keyboard 94 to enable information, such as the rotor speed and known motor parameter data, to be inputted into the processor module 84. In addition, in this embodiment, the processor module 84 and the control module 90 are coupled to a network 96 to enable data to be transmitted to and from remote terminals 98. The remote terminals or work stations 98 may be personal computers, or other computer communication devices.

Referring generally to FIG. 4, a process for providing estimated values of various motor parameters using the system of FIG. 3 is shown and designated generally by reference numeral 100. The illustrated process 100 comprises providing known motor data, motor input data, and rotor speed data to the electronics module 82, as represented by block 102. Examples of known motor data include the stator resistance R₁, the stator leakage inductance L₁, the core loss resistance R_{c}, and the magnetizing inductance Lₘ. Examples of motor input data include the input voltage amplitude V₁, frequency ω, and the power factor. The rotor speed data, such as the RPM or slip s of the rotor, is an example of motor output data.

The process also comprises using the processor module 84 to process the known motor parameter data, the input power data, and rotor speed data to develop an estimate of at least one unknown motor parameter during operation of the rotor, as represented by block 104. Referring again to FIG. 2, the equivalent circuit provides a starting point for the development of a process for estimating various motor operating parameters. FIG. 2 illustrates the single-phase steady-state equivalent circuit of an induction motor with a sinusoidal input. From this circuit, the steady-state circuit of FIG. 2 may be represented by the three equations provided below.

$$\begin{matrix}{I}_{1} * {R}_{1} + {L}_{1} * \frac{ⅆ {I}_{l}}{ⅆ t} + {R}_{c} * ( {I}_{1} - {I}_{3} ) = {V}_{1} ; & ( 1 ) \\ {R}_{c} * ( {I}_{3} - {I}_{1} ) + {L}_{m} * \frac{ⅆ ( {I}_{3} - {I}_{2} )}{ⅆ t} = 0 ; and & ( 2 ) \\ {L}_{2} * \frac{ⅆ {I}_{2}}{ⅆ t} + \frac{{R}_{2}}{s} * {I}_{2} + {L}_{m} * \frac{ⅆ ( {I}_{2} - {I}_{3} )}{ⅆ t} = 0. & ( 3 )\end{matrix}$$

The three equations provided above may be used to develop an equation for the stator current I₁. The three equations provided above may be written in matrix form, as follows:

$$[ \begin{matrix}\frac{ⅆ {I}_{1}}{ⅆ t} \\ \frac{ⅆ {I}_{2}}{ⅆ t} \\ \frac{ⅆ {I}_{3}}{ⅆ t}\end{matrix} ] = [ \begin{matrix}- ( \frac{{R}_{1}}{{L}_{1}} + \frac{{R}_{c}}{{L}_{1}} ) & 0 & \frac{{R}_{c}}{L1} \\ \frac{{R}_{c}}{{L}_{2}} & - \frac{{R}_{2}}{s {L}_{2}} & - \frac{{R}_{c}}{{L}_{2}} \\ ( \frac{{R}_{c}}{{L}_{m}} + \frac{{R}_{c}}{{L}_{2}} ) & - \frac{{R}_{2}}{s {L}_{2}} & - ( \frac{{R}_{c}}{{L}_{2}} + \frac{{R}_{c}}{{L}_{m}} )\end{matrix} ] [ \begin{matrix}{I}_{1} \\ {I}_{2} \\ {I}_{3}\end{matrix} ] + [ \begin{matrix}\frac{1}{{L}_{1}} \\ 0 \\ 0\end{matrix} ] {V}_{1} \qquad ( 4 )$$

It may be noted that equation (4) is in the form of:

$$\frac{ⅆ X}{ⅆ t} = AX + BU \qquad ( 5 )$$

The following equation for the stator current I₁, is obtained by taking the Laplace Transform of equation (4) and solving:

$$\begin{matrix}{I}_{1} ( S ) = \frac{{V}_{1} ( S ) \frac{1}{{L}_{1}} * ( {S}^{2} + ( \frac{{R}_{2}}{s {L}_{2}} + \frac{{R}_{c}}{{L}_{2}} + \frac{{R}_{c}}{{L}_{m}} ) S + \frac{{R}_{2} {R}_{c}}{s {L}_{2} L m} )}{{S}^{3} + {S}^{2} {m}_{2} + {S}^{1} {m}_{1} + {m}_{0}} . \\ where & ( 6 ) \\ {m}_{0} = \frac{{R}_{1} {R}_{2} {R}_{c}}{s {L}_{1} {L}_{2} {L}_{m}} ; & ( 7 ) \\ {m}_{1} = \frac{{R}_{1} {R}_{2}}{s {L}_{1} {L}_{2}} + \frac{{R}_{2} {R}_{c}}{s {L}_{2} {L}_{m}} + \frac{{R}_{1} {R}_{c}}{{L}_{1} {L}_{2}} + \frac{{R}_{1} {R}_{c}}{{L}_{1} {L}_{m}} + \frac{{R}_{2} {R}_{c}}{s {L}_{1} {L}_{2}} ; and & ( 8 ) \\ {m}_{2} = \frac{{R}_{1}}{{L}_{1}} + \frac{{R}_{2}}{s {L}_{2}} + \frac{{R}_{c}}{{L}_{1}} + \frac{{R}_{c}}{{L}_{2}} + \frac{{R}_{c}}{{L}_{m}} . & ( 9 )\end{matrix}$$

In the exemplary embodiment of the present technique, all of the parameters of equation (6) are known or easily measurable, except for the rotor resistance R₂. The rotor resistance R₂ is difficult to measure because of its variation as a function of rotor temperature and the difficulty in measuring the rotor temperature.

The rotor resistance R₂ is estimated by equating the expression for the stator current I₁ to the measured value of stator current I₁. To reduce the amount of calculations to be performed to obtain the various operational motor parameters, the stator current I₁ is assumed to have a zero phase angle and the input voltage is assumed to be leading the current. This enables the imaginary part of the stator current I₁ to be equated to zero. Two goals are achieved by making the imaginary part of the stator current I₁ equal to zero. First, the measured amplitude of the current need not be used in the calculation, thereby reducing the number of calculations to be performed. Second, the denominator of the current expression need not be considered, again reducing the number of calculations. From this, the following equations for voltage and current may be obtained:

V₁(t)=V₁ₛ sin(ωt)+V_{1c} cos(ωt); (10)

and

I₁(t)=I₁ₛ sin(ωt). (11)

V₁ₛ is the amplitude of the sine wave of input voltage V₁ and is a function of the amplitude of the power source voltage V₁ and the cosine of the phase angle. V_{1c} is the amplitude of the cosine wave of the input voltage and is a function of the amplitude of the power source voltage V₁ and the sine of the phase angle. I₁ₛ is the amplitude of the stator current I₁. The Laplace transform of the voltage equation provided above is given by:

$${V}_{1} ( S ) = \frac{{V}_{1 c} S + {V}_{1 s} ω}{{S}^{2} + {ω}^{2}} . \qquad ( 12 )$$

Substituting the Laplace transform into the input current equation and factoring the denominator produces the following equation for the stator current I₁:

$${I}_{1} ( S ) = \frac{a S + b}{{S}^{2} + {ω}^{2}} + \frac{c {S}^{2} + d S + e}{{S}^{3} + {m}_{2} {S}^{2} + {m}_{1} S + {m}_{0}} . \qquad ( 13 )$$

An equation for the rotor resistance R₂ during motor operation may be developed from stator current I¹ equation (13) provided above. Since the equivalent circuit is based on the steady state operation of the motor, the second term is omitted after finding the coefficients “a” and “b”. Five equations and five unknowns are obtained by solving the equations for the constants “a”, “b”, “c”, “d”, and “e” and equating the coefficients of the original numerator to the present numerator. Only the numerator of the constant “a” is needed when the coefficient of the cosine is set equal to zero. Thus, the numerator of a becomes:

$$Numerator of a = P1 * ( {m}_{1} - {ω}^{2} ) - P2 * ( {m}_{2} - \frac{{m}_{0}}{{ω}^{2}} ) . \qquad ( 14 )$$

Where P1 and P2 are given by:

$$\begin{matrix}P1 = \frac{{V}_{1 s} {R}_{2} {R}_{c}}{s {L}_{1} {L}_{2} {L}_{m} ω} + \frac{{V}_{1 s} ω}{{L}_{1}} + \frac{{V}_{1 c}}{{L}_{1}} ( \frac{{R}_{c}}{{L}_{m}} + \frac{{R}_{c}}{{L}_{2}} + \frac{{R}_{2}}{s {L}_{2}} ) ; and & ( 15 ) \\ P2 = \frac{{V}_{1 s} ω}{{L}_{1}} ( \frac{{R}_{c}}{{L}_{m}} + \frac{{R}_{c}}{{L}_{2}} + \frac{{R}_{2}}{s {L}_{2}} ) + \frac{{V}_{1 c} {R}_{2} {R}_{c}}{s {L}_{1} {L}_{2} {L}_{m}} - \frac{{V}_{1 c} {ω}^{2}}{{L}_{1}} . & ( 16 )\end{matrix}$$

Equating the numerator to zero, a quadratic equation is obtained for the rotor resistance R₂ of the form:

A*R₂²+B*R₂+C=0 (17)

Where A, B, and C are given by:

$$\begin{matrix}A = ( \frac{{R}_{1}}{{s}^{2} {L}_{1}^{2} {L}_{2}^{2}} + \frac{{R}_{c}}{{s}^{2} {L}_{1}^{2} {L}_{2}^{2}} + \frac{{R}_{1} {R}_{c}^{2}}{{s}^{2} {L}_{1}^{2} {L}_{2}^{2} {L}_{m}^{2} {ω}^{2}} ) * {V}_{1 c} - ( \frac{{R}_{c}^{2}}{{s}^{2} {L}_{1}^{2} {L}_{2}^{2} {L}_{m}^{2} ω} + \frac{{R}_{c}^{2}}{{s}^{2} {L}_{1}^{2} {L}_{2}^{2} {L}_{m} ω} + \frac{ω}{{s}^{2} {L}_{1} {L}_{2}^{2}} ) * {V}_{1 s} & ( 18 ) \\ B = ( \frac{2 {R}_{c} {R}_{1}}{s {L}_{1}^{2} {L}_{2}^{2}} + \frac{{R}_{c}^{2}}{s {L}_{1}^{2} {L}_{2}^{2}} ) * {V}_{1 c} - ( \frac{2 {R}_{c} ω}{s {L}_{1} {L}_{2}^{2}} ) * {V}_{1 s} , and & ( 19 ) \\ C = ( \frac{{R}_{1} {R}_{c}^{2}}{{L}_{1}^{2} {L}_{2}^{2}} + \frac{2 {R}_{1} {R}_{c}^{2}}{{L}_{1}^{2} {L}_{2} {L}_{m}} + \frac{{R}_{1} {ω}^{2}}{{L}_{1}^{2}} + \frac{{R}_{c} {ω}^{2}}{{L}_{1}^{2}} + \frac{{R}_{1} {R}_{c}^{2}}{{L}_{1}^{2} {L}_{m}^{2}} ) * {V}_{1 c} - ( \frac{{ω}^{3}}{{L}_{1}} + \frac{{R}_{c}^{2} ω}{{L}_{1}^{2} {L}_{2}} + \frac{{R}_{c}^{2} ω}{{L}_{2}^{2} {L}_{1}} + \frac{2 {R}_{c}^{2} ω}{{L}_{2}^{2} {L}_{1}} + \frac{{R}_{c}^{2} ω}{{L}_{1}^{2} {L}_{m}} + \frac{{R}_{c}^{2} ω}{{L}_{m}^{2} {L}_{1}} ) * {V}_{1 s} . & ( 20 )\end{matrix}$$

Thus, from the quadratic equation (17) provided above, the following equation for the rotor resistance R₂ is obtained:

$${R}_{2} = - \frac{B}{2 A} + \frac{1}{2 A} \sqrt{{B}^{2} - 4 AC} . \qquad ( 21 )$$

In solving equation (21), the minus sign that would normally be present in the solution to the quadratic equation is omitted because it yields a lower resistance as the rotor temperature increases, contrary to the actual physical properties of the rotor.

From equations (18)-(20) provided above, the values used in equation (21) to estimate the rotor resistance R₂ are: the stator resistance R₁, the stator leakage inductance L₁, the core loss resistance R_{c}, the magnetizing inductance Lₘ, the rotor leakage inductance L₂, the power source voltage amplitude V₁, the sinusoidal component of the power source voltage V₁ₛ, the amplitude of the cosine portion of the power source voltage V_{1c}, the power source frequency ω, and the slip s of the rotor. The stator resistance R₁, the stator leakage inductance L₁, the core loss resistance R_{c}, the magnetizing inductance Lₘ, and the rotor leakage inductance L₂ are electrical parameters for a given motor. The power source voltage amplitude V₁, the amplitude of the sine portion of the power source voltage V₁ₛ, the amplitude of the cosine portion of the power source voltage V_{1c}, and the power source frequency ω are input motor parameters. In addition, the power factor is another input motor parameter that is used. The power factor is used with the power source voltage amplitude V₁ to establish V₁ₛ and V_{1c}. The slip s is a motor output parameter.

As discussed above, the control module 90 may be used to input known motor parameter data. Alternatively, the motor parameter data may be pre-programmed into the processor module 84. Preferably, the input power is electrically coupled to the electronics module 82 to provide the input power data to the processor module 84. However, the control module 90 may be used to input the data to the electronics module 82. Preferably, the rotor speed may be provided by an internal or external sensor that is electrically coupled to the electronics module 82. However, the rotor speed data may also be inputted via the control module 90. In addition, data may be provided from a remote work station 98 via the network 96. The processor module 84 is operable to take the data and produce an estimated value of the rotor resistance R₂ using the technique provided above.

Referring again to FIG. 4, an estimated value of one motor parameter may be used to develop estimates of other motor parameters, as represented by block 106. For example, the rotor resistance R₂ may be used to establish an estimated value of the rotor temperature, the rotor current I₂, the motor torque, and the motor efficiency. The temperature of the rotor during motor operation may be estimated using the estimated value of the rotor resistance R₂ and the following equation relating changes in electrical resistance of the rotor to changes in temperature:

R₂ₕₒₜ=R_{2cold}(1+α(Tₕₒₜ−T_{cold})) (22)

where: R_{2 cold} is the rotor resistance at a first temperature; R_{2 hot} is the rotor resistance at a second temperature; T_{cold} is the rotor temperature at a first temperature; Tₕₒₜ is the rotor temperature at a second temperature; and α is the temperature coefficient of electrical resistance of the rotor in Ω/unit of temperature.

As an example, the above equation may be manipulated algebraically to obtain the following equation for an aluminum rotor:

$${T}_{hot} = \frac{{R}_{2 hot}}{{R}_{2 cold}} * ( 225 + {T}_{cold} ) - 225 \qquad ( 23 )$$

The value used for R_{2 hot} is the estimated value for the rotor resistance R₂ at the second temperature Tₕₒₜ. The control module 90 may be used to input the rotor temperature at the first temperature T_{cold} and the rotor resistance at the first temperature R_{2 cold} In addition, the data may be provided by the remote work stations 98 via the network 96.

To validate the equations, the techniques described above were compared to values obtained using a motor design program. The following values were provided to the motor design program:

$$\begin{matrix}Input Voltage {V}_{1} = 575 V \\ Speed at full load = 1173.6 RPM \\ Frequency ω = 120 π rad \text{/} s \\ Power Factor = 0.822 \\ Stator Resistance hot {R}_{1 Hot} = 0.0228 \\ Rotor Resostance cold {R}_{2 Cold} = 0.01515 \\ Rotor Resostance hot {R}_{2 Hot} = 0.01795 \\ {r}_{m} = 0.05035 \\ Stator Leakage Reactance {X}_{1} = 0.08424 \\ Stator Leakage Reactance {X}_{2} = 0.11197 \\ Magnetizing Reactance {X}_{m} = 1.8079\end{matrix}$$

These values are per unit values based on the stator resistance. These parameters were converted to the following parameters used in the equations:

$$\begin{matrix}Core Loss Resistance {R}_{c} = 64.915 \\ Magnetizing Inductance {L}_{m} = 0.00479 \\ Stator Leakage Inductance {L}_{1} = 0.0002234 \\ Rotor Leakage Inductance {L}_{2} = 0.000297 \\ {V}_{1 s} = 385.9 V \\ {V}_{1 c} = 267.3 V \\ Slip s = 0.022\end{matrix}$$

The above values produced an estimated value of rotor resistance R₂ of 0.017229 versus a design program value of rotor resistance R₂ of 0.01727. These values also are per unit values. The normalized value of the rotor resistance is 44.32Ω.

The current flowing through the rotor during motor operation also may be estimated. The rotor current I₂ may be estimated from the estimated value of rotor resistance R₂. For example, I₂(S) is solved from the motor matrix discussed above, as follows:

$${I}_{2} ( S ) = \frac{\frac{{V}_{1} ( S ) * {R}_{c}}{{L}_{1} {L}_{2}} * S}{{S}^{3} + {m}_{2} {S}^{2} + {m}_{1} S + {m}_{0}} \qquad ( 24 )$$

The equivalent of V₁(S) from equation (12) provided above may then be substituted into equation (24). In addition, the equivalent circuit is for steady-state operation of the motor. Therefore, when expressing equation (25) as a partial fraction, the transient portion may be omitted, producing the following equation:

I₂(t)=a₁ cos(ωt)+b₁ sin(ωt) (25)

where,

$$\begin{matrix}{a}_{1} = \frac{\frac{{V}_{1 c} {R}_{c}}{{L}_{1} {L}_{2}} ( {m}_{1} - {ω}^{2} ) - \frac{{V}_{1 s} {R}_{c} ω}{{L}_{1} {L}_{2}} ( {m}_{2} - {m}_{0} / - {ω}^{2} )}{{( {m}_{1} - {ω}^{2} )}^{2} + {( {m}_{2} ω - {m}_{0} / ω )}^{2}} ; and & ( 26 ) \\ {b}_{1} = \frac{\frac{{V}_{1 s} {R}_{c}}{{L}_{1} {L}_{2}} ( {m}_{1} - {ω}^{2} ) - \frac{{V}_{1 c} {R}_{c}}{{L}_{1} {L}_{2} ω} ( {m}_{0} - {m}_{2} {ω}^{2} )}{{( {m}_{1} - {ω}^{2} )}^{2} + {( {m}_{2} ω - {m}_{0} / ω )}^{2}} . & ( 27 )\end{matrix}$$

The amplitude of the rotor current I₂ is obtained from a₁ and b₁, as provided below:

I_{2 amplitude}=\sqrt{a₁²+b₁²}. (28)

The RMS value of the rotor current I₂ is:

$${I}_{2 r m s} = \sqrt{\frac{{a}_{1}^{2} + {b}_{1}^{2}}{2}} . \qquad ( 29 )$$

The torque of the rotor during motor operation also may be estimated. The motor torque may also be estimated using the estimated values of rotor resistance R₂ and rotor current I₂, in accordance with the relationship.

$$mechanical torque ( in Newton \text{-} meters ) = \frac{3 * {I}_{2 r m s}^{2} * {R}_{2}}{{ω}_{s} * s} . \qquad ( 30 )$$

where: ωₛ is the synchronous mechanical speed of the rotor,f is the electrical frequency, and p is the number of poles of the rotor.

The control module 90 may be used to input the synchronous mechanical speed of the rotor ωₛ and the electrical frequency f, and the number of poles p of the rotor. Alternatively, the data may be pre-programmed into the processor module 84. In addition, the data may be provided by the remote work stations 98 via the network 96. The processor module 84 is operable to take the data and produce an estimated value of the motor torque using the technique provided above. To obtain the torque in ft-lbf the torque in Newton-meters is multiplied by 0.738.

Other motor operating parameters may be estimated as well. For example, the motor efficiency may be estimated by dividing the estimated output mechanical power by the input electrical power.

$$η = \frac{{P}_{out}}{{P}_{i n}} \qquad ( 31 )$$

Thus, the above-described technique enables a number of unknown motor parameters, such as rotor temperature, torque, and efficiency, to be estimated accurately during the operation of the motor without interfering with the operation of the motor. For example, the technique enables the rotor temperature to be estimated without the use of a temperature probe. In addition, the technique enables the torque of the motor to be estimated without the use of a torque meter and without disconnecting the motor from its load.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

What is claimed is:

1. An information system for an electric motor having a stator and a rotor, comprising:
a processing module that is operable to establish an estimated value of a motor parameter that is variable during motor operation based on motor electrical input data, rotor and stator electrical characteristics data, and rotor speed data.

2. The system as recited in claim 1, wherein the motor parameter is electrical resistance of the rotor.

3. The system as recited in claim 1, wherein the motor parameter is rotor temperature.

4. The system as recited in claim 1, wherein the motor parameter is motor torque.

5. The system as recited in claim 1, wherein the motor electrical input data comprises at least one of input voltage, input current, input frequency, power factor, and input power.

6. The system as recited in claim 1, wherein the rotor and stator electrical characteristics data comprises stator resistance, stator inductance, rotor inductance, core loss resistance, and magnetizing inductance.

7. The system as recited in claim 1, comprising a visual display operable to provide a visual indication of the estimated value of the variable motor parameter.

8. The system as recited in claim 1, comprising:
a communication module to enable at least one of the motor electrical input data, the known rotor and stator electrical characteristics data, and the rotor speed data to be inputted into the system.

9. An information system for an electric motor having a stator and a rotor, comprising:
a processing module that operates in accordance with programming instructions to establish an estimated value of electrical resistance of the rotor based on rotor speed data.

10. The system as recited in claim 9, wherein the processing module establishes an estimated value of rotor temperature during operation of the motor based on the estimated value of the electrical resistance of the rotor.

11. The system as recited in claim 9, wherein the processing module establishes an estimated value of electric current through the rotor during operation of the motor based on the estimated value of the electrical resistance of the rotor.

12. The system as recited in claim 9, wherein the processing module establishes an estimated value of motor torque during operation of the motor based on the estimated value of the electrical resistance of the rotor.

13. The system as recited in claim 9, wherein the estimated value of electrical resistance of the rotor during operation of the motor is based on known motor electrical characteristics data provided to the system.

14. The system as recited in claim 13, wherein the known electrical characteristics of the motor data comprises stator resistance, stator leakage inductance, rotor leakage inductance, core loss resistance, and magnetizing inductance.

15. The system as recited in claim 13, comprising an input system adapted to enable the known electrical characteristics of the motor data to be inputted to the system.

16. An electric motor system, comprising:
a rotor;
a stator; and
a processing module that is operable to establish an estimated value of rotor temperature based on rotor speed data obtained during operation of the motor.

17. The system as recited in claim 16, comprising a visual display operable to provide a visual indication of rotor temperature.

18. The system as recited in claim 16, wherein the estimated value of rotor temperature is based on motor input power data and known rotor and stator electrical data.

19. The system as recited in claim 18, comprising:
an input module to enable the at least one of the motor input power data, the known rotor and stator electrical data, and the rotor speed data to be provided to the system.

20. An electric motor, comprising:
a stator;
a rotor, and
a processing device that operates to establish an estimated value of a motor parameter that varies due to heating of the motor, the estimated value being based on speed of the rotor.

21. The motor as recited in claim 20, wherein the estimated value of a motor characteristic is based on electrical power data.

22. The motor as recited in claim 20, wherein the estimate value of a motor parameter is based on known rotor and stator electrical characteristics data.

23. The motor as recited in claim 22, comprising a control module adapted to enable the known rotor and stator electrical characteristics data to be provided to the processing device.

24. The motor as recited in claim 20, wherein the motor parameter is electrical resistance of the rotor.

25. The motor as recited in claim 20, wherein the motor parameter is temperature of the rotor.

26. The motor as recited in claim 20, wherein the motor parameter is torque of the motor.

27. The motor as recited in claim 20, comprising a communications device to enable the processing device to communicate with an external electronic device.

28. A method of estimating a parameter of an electric motor having a rotor and a stator, comprising:
providing rotor speed data to an electronic system;
providing motor input data to the electronic system; and
operating the electronic system to establish an estimated value of a variable motor parameter during operation of the motor based on the rotor speed data, the motor input data, and rotor and stator data programmed into the electronic system.

29. The method as recited in claim 28, further comprising programming the electronic system with rotor and stator data.

30. The method as recited in claim 29, wherein providing rotor and stator data comprises providing rotor leakage inductance data, stator resistance data, stator leakage inductance data, core loss resistance data, and magnetizing inductance data to the electronic system.

31. The method as recited in claim 28, wherein providing motor input data comprises providing input voltage amplitude and frequency data to the electronic system.

32. The method as recited in claim 28, wherein the variable motor parameter is electrical resistance of the rotor.

33. The method as recited in claim 28, wherein the variable motor parameter is rotor temperature.

34. The method as recited in claim 28, wherein the variable motor parameter is rotor torque.

35. A system for estimating an operating parameter of an electric motor having a rotor and a stator, comprising:
means for providing rotor speed data to an electronic system;
means for providing input power data to the electronic system; and
means for operating the electronic system to establish an estimated value of a rotor parameter based on the rotor speed and the motor input data.

36. The system as recited in claim 35, further comprising means for providing motor characteristic data to the electronic system.

37. The system as recited in claim 35, wherein the means for operating the electronic system comprises means for operating the electronic system to establish the estimated value of a rotor parameter based on the rotor speed, the motor input data, and the motor characteristic data.
